(19) United States
(12) Patent Application Publication
(10) Pub. No.: US 2012/0229306 A1
(43) Pub. Date: Sep. 13, 2012

(54) TOUCH SENSITIVE KEYBOARD WITH TOUCH TEXTURE

(75) Inventor: Yu-Kai LIN, Zhonghe City (TW)

(73) Assignee: KO JA (CAYMAN) CO., LTD.

(21) Appl. No.: 13/043,705

(22) Filed: Mar. 9, 2011

(51) Int. Cl. H03K 17/94

(52) U.S. Cl. 341/22

(57) ABSTRACT

A touch sensitive keyboard includes a bottom board, at least one sensing layer, a surface layer and a protruding print layer. The sensing layer is disposed on the bottom board and includes a plurality of sensors; the surface layer is stacked on the sensing layer and has a first surface disposed towards the sensing layer and opposite to the second surface; the protruding print layer is printed onto the second surface and includes a plurality of bumps protruded with a predetermined distance from the second surface, such that when the surface layer and the protruding print layer are touched simultaneously, the surface layer and the protruding print layer can be distinguished to provide a texture feedback mechanism, and users can assure that a specific position of the keyboard is touched, so as to enhance the user experience of using the keyboard.

### FIELD OF THE INVENTION

The present invention relates to a keyboard, in particular to a touch sensitive keyboard.

### BACKGROUND OF THE INVENTION

Keyboard is a necessary peripheral of a computer and provided for users to input an operating instruction to execute a specific function. However, the keyboard used for desktop or notebook computers comes with a mechanical press-key design for function keys, a keypad and hot keys of the keyboard, except a touch pad for controlling a cursor.

In the foregoing conventional keyboard, the touch pad and the mechanical press keys have different operating principles and thus require different manufacturing processes, and it is necessary to manufacture them separately during the manufacture of the keyboard, which causes inconvenience to manufacturers. Furthermore, foreign substances such as dusts or liquids may fall into gaps of the mechanical press keys and cause damages to the mechanical press keys easily, after the keyboard has been used for a while. As a result, the keyboard may fail to input operating signals and cause problems to the use of the keyboard.

In recent years, related manufacturers actively develop a virtual keyboard device on a touch sensitive panel, but the virtual keyboard device does not have any touch texture of pressing the key or any touch texture of the key stroke, so that users have to find out whether or not they have touched the correct position through the corresponding display screen. For the application of the virtual keyboard device, it is a fly in an ointment.

In view of the aforementioned shortcomings of the prior art, the inventor of the present invention based on years of experience in the related industry to conduct extensive researches and experiments, and finally provided a feasible solution in accordance with the present invention to overcome the shortcomings of the prior art.

### SUMMARY OF THE INVENTION

Therefore, it is a primary objective of the present invention to provide a touch sensitive keyboard with a touch texture, comprising a bump printed at a specific position to provide a touch feedback mechanism for users to assure that the specific position is touched, so as to enhance the convenience of using the keyboard.

Another objective of the present invention is to provide a touch sensitive keyboard with a touch texture, and the keyboard has the advantages of a low cost, a high precision and a good appearance since the bump is formed at a specific position by printing.

To achieve the foregoing objectives, the present invention provides a touch sensitive keyboard with a touch texture, comprising a bottom board, at least one sensing layer, a surface layer and a protruding print layer, wherein the sensing layer is disposed on the bottom board and has a plurality of sensors; the surface layer is stacked on the sensing layer and has a first surface disposed towards the sensing layer and opposite to the second surface; and the protruding print layer is printed onto the second surface and includes a plurality of bumps protruded with a predetermined distance from the second surface, such that when the surface layer and the protruding print layer are touched simultaneously, the surface layer and the protruding print layer can be distinguished.

A further objective of the present invention is to provide a touch sensitive keyboard with a touch texture, wherein the bumps can be of different shapes such as the shape of a dot, a frame, or a star to achieve the advantages of different protruding points.

Compared with the prior art, the touch sensitive keyboard with a touch texture of the present invention prints the protruding print layer onto the external side of the surface layer, and the protruding print layer includes a plurality of bumps protruded with a predetermined distance from the surface layer, such that when a user touches the touch sensitive keyboard, the user can feel his or her finger touching the protruding print layer to provide a touch feedback mechanism and let the user know that the specific position is touched, so as to enhance the convenience of using the keyboard. Since the present invention forms the bumps at specific positions by printing, the invention has the advantages of a low cost, a high precision and a good appearance and achieves the effect of different protruding points to improve the applicability and cost-effectiveness over the conventional way of attaching or sticking the bumps at the specific positions.

### BRIEF DESCRIPTION OF THE DRAWINGS

FIG. 1 is a perspective exploded view of a touch sensitive keyboard in accordance with the present invention;

FIG. 2 is a schematic perspective view of a surface layer of the present invention;

FIG. 3 is a cross-sectional view of a surface layer of the present invention;

FIG. 4 is a schematic perspective view of a touch sensitive keyboard of the present invention;

FIG. 5 is a cross-sectional view of a touch sensitive keyboard of the present invention; and

FIG. 6 is a schematic view of a protruding print layer in accordance with a second preferred embodiment of the present invention.

### DESCRIPTION OF THE PREFERRED EMBODIMENTS

The technical characteristics and contents of the present invention will become apparent with the following detailed description and related drawings. The drawings are provided for the purpose of illustrating the present invention only, but not intended for limiting the scope of the invention.

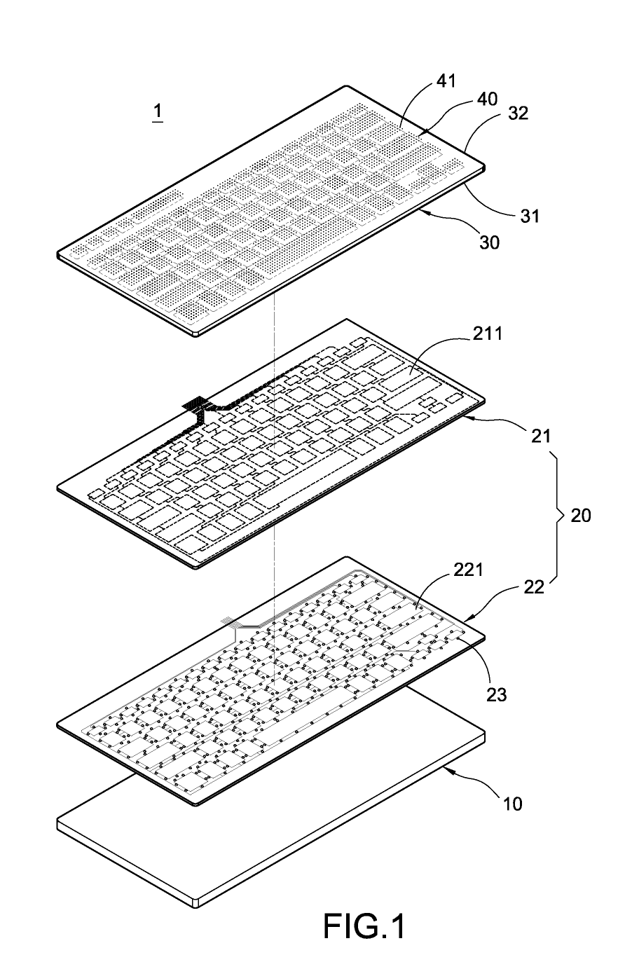

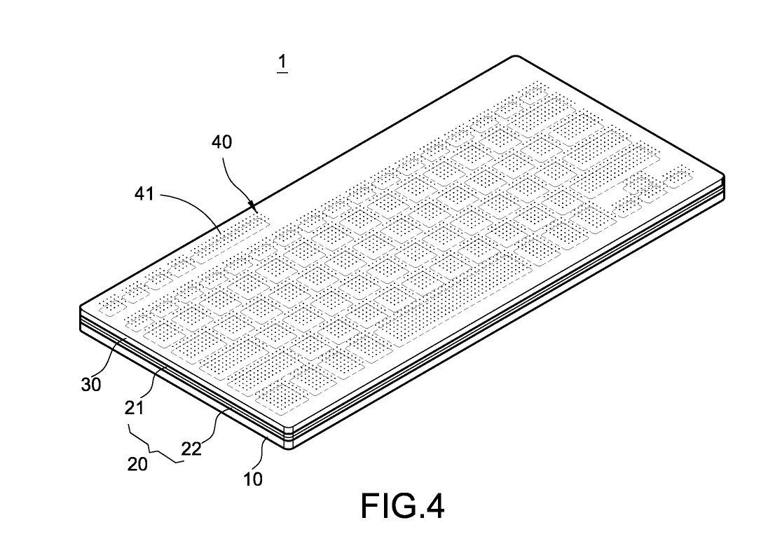

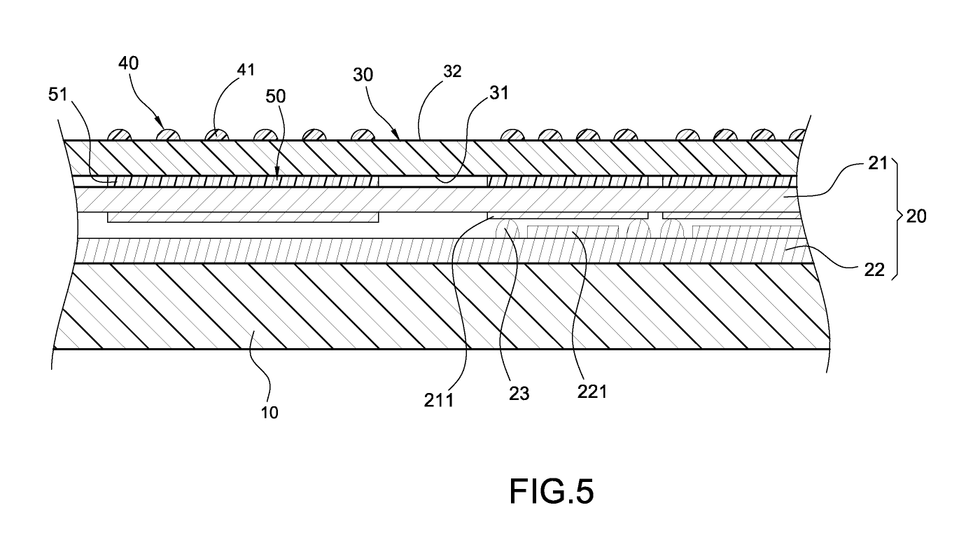

With reference to FIGS. 1 to 5 for a perspective exploded view of a touch sensitive keyboard with a touch texture, a schematic perspective view and a cross-sectional view of a surface layer, a schematic perspective view and a perspective cross-sectional view of a touch sensitive keyboard of the present invention respectively, the touch sensitive keyboard 1 comprises a bottom board 10, at least one sensing layer 20, a surface layer 30 and a protruding print layer 40.

The bottom board 10 is a support board provided for carrying the sensing layer 20, the surface layer 30 and the protruding print layer 40.

The touch sensitive keyboard 1 includes at least one sensing layer 20 installed on the bottom board 10, and the sensing layer 20 is a touch sensitive switch having a plurality of sensors for detecting touch points, and the sensing layer 20 is a resistive touch sensitive switch, a capacitive touch sensitive switch, or a complex resistive/capacitive touch sensitive switch. In this preferred embodiment, the sensing layer 20 includes a first conductive layer 21 and a second conductive layer 22, and the first conductive layer 21 includes a plurality of first sensors 211, and the second conductive layer 22 includes a plurality of second sensors 221. The sensing type of the first sensor 211 and the second sensor 221 is not limited to those described above, but it can be changed according to the requirement of different practical applications. In addition, when the first sensor 211 includes the resistive touch sensitive switch, a plurality of support members 23 is installed between the first conductive layer 21 and the second conductive layer 22 to form a gap between the first conductive layer 21 and the second conductive layer 22.

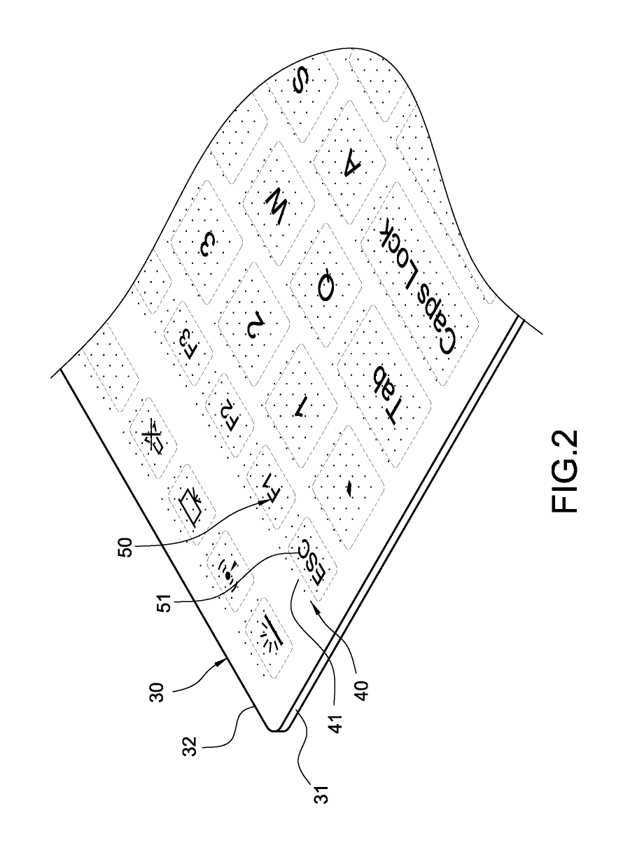

The surface layer 30 is stacked on an external side of the sensing layer 20 and has a first surface 31 disposed towards the sensing layer and opposite to the second surface 32. In this preferred embodiment, the first surface 31 of the surface layer 30 further includes a keyboard text layer 50 (as shown in FIG. 2), and the keyboard text layer 50 includes a plurality of text symbols 51 used for mapping English alphabets or numbers of a conventional keyboard.

The protruding print layer 40 is composed of ink, and the protruding print layer 40 is printed onto the second surface 32, and the protruding print layer 40 includes a plurality of bumps 41, and the bumps 41 are protruded with a predetermined distance from the second surface 32. Preferably, the bumps 41 are protruded with a distance of approximately 0.05 mm˜0.8 mm from the second surface 32, such that when the surface layer 30 and the protruding print layer 40 are touched simultaneously, the surface layer 30 and the protruding print layer 40 can be distinguished.

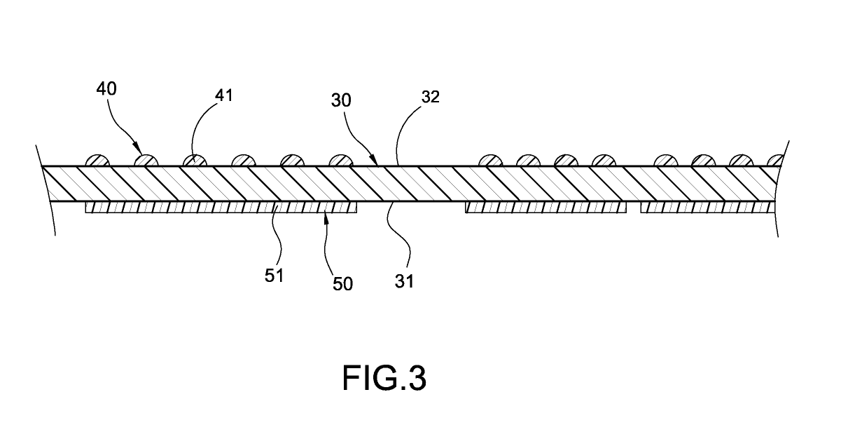

The bumps 41 are disposed corresponding to the text symbols 51 on the keyboard text layer 50 respectively, and each of the bump 41 of this preferred embodiment is substantially in the shape of a protruding dot (as shown in FIG. 3), and the bumps 41 are disposed at positions corresponding to the text symbols 51 and arranged above the text symbols 51 respectively. Further, the bump 41 can be of other shapes such as the shape of a point, a frame or a star to achieve the advantages of different protruding points.

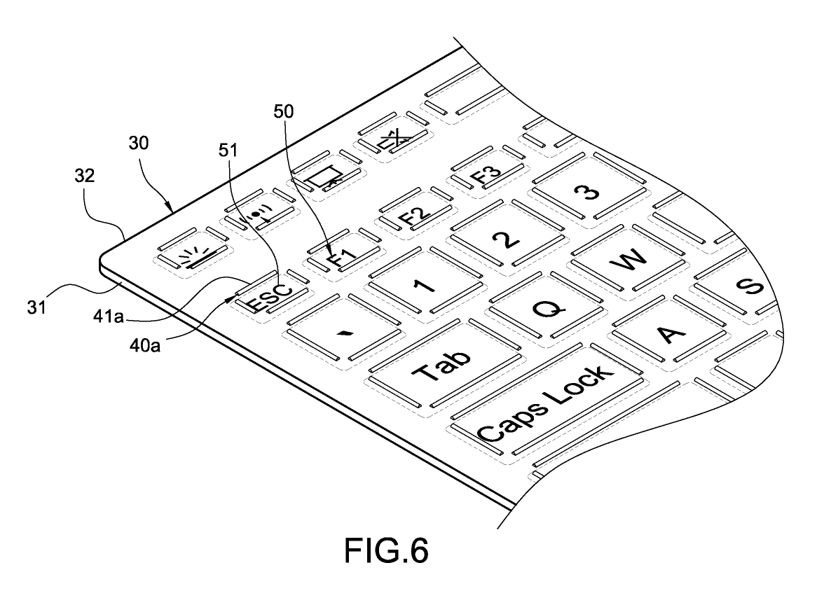

With reference to FIG. 6 for a protruding print layer in accordance with a second preferred embodiment of the present invention, the difference of this preferred embodiment and the first preferred embodiment resides on that the first surface 31 of the surface layer 30. This preferred embodiment also includes a keyboard text layer 50, and the keyboard text layer 50 includes a plurality of text symbols 51 for mapping English alphabets and numbers of a conventional keyboard. And the protruding print layer 40a is formed on the second surface 32 by printing, and the protruding print layer 40a includes a plurality of bumps 41a, and each of the bumps 41a is substantially in a rectangular shape, and the bumps 41a are disposed at positions corresponding to the text symbols 51 and arranged on lateral sides of the text symbols 51 respectively.

In summation of the description above, the present invention improves over the prior art and complies with the patent application requirements, and thus is duly filed for patent application.

While the invention has been described by means of specific embodiments, numerous modifications and variations could be made thereto by those skilled in the art without departing from the scope and spirit of the invention set forth in the claims.

What is claimed is:

1. A touch sensitive keyboard with a touch texture, comprising:
a bottom board;
at least one sensing layer, disposed on the bottom board, and having a plurality of sensors;
a surface layer, stacked on the sensing layer, and having a first surface disposed towards the sensing layer and opposite to the second surface; and
a protruding print layer, printed onto the second surface, and including a plurality of bumps protruded with a predetermined distance from the second surface;
such that when the surface layer and the protruding print layer are touched simultaneously, the surface layer and the protruding print layer can be distinguished.

2. The touch sensitive keyboard with a touch texture as recited in claim 1, wherein the sensing layer includes a first conductive layer, and the first conductive layer includes a plurality of first sensors.

3. The touch sensitive keyboard with a touch texture as recited in claim 2, wherein the sensing layer further includes a second conductive layer, and the second conductive layer includes a plurality of second sensors.

4. The touch sensitive keyboard with a touch texture as recited in claim 3, wherein the first sensors include at least one resistive touch sensitive switch and a plurality of support members disposed between the first conductive layer and the second conductive layer.

5. The touch sensitive keyboard with a touch texture as recited in claim 1, wherein the first surface of the surface layer further includes a keyboard text layer, and the keyboard text layer includes a plurality of text symbols.

6. The touch sensitive keyboard with a touch texture as recited in claim 5, wherein the bumps are installed corresponding to the keyboard text layer.

7. The touch sensitive keyboard with a touch texture as recited in claim 6, wherein each of the bumps is substantially in the shape of a protruding dot, and the bumps are disposed at positions corresponding to the text symbols and arranged above the text symbols respectively.

8. The touch sensitive keyboard with a touch texture as recited in claim 6, wherein each of the bumps is substantially in a rectangular shape, and the bumps are disposed at positions corresponding to the text symbols and arranged on lateral sides of the text symbols respectively.

9. The touch sensitive keyboard with a touch texture as recited in claim 1, wherein the bumps are protruded with a distance of approximately equal to 0.05 mm˜0.8 mm from the second surface.
